(19) United States
(12) Patent Application Publication
(10) Pub. No.: US 2008/0169269 A1
(43) Pub. Date: Jul. 17, 2008

(54) METHOD FOR PROCESSING WAFER IN REACTION CHAMBER

(75) Inventor: Chen Lung Fan, Hsinchu (TW)

Correspondence Address: WPAT, PC;INTELLECTUAL PROPERTY ATTORNEYS, 2030 MAIN STREET, SUITE 1300, IRVINE, CA, 92614, US

(73) Assignee: LAM RESEARCH CO., LTD, Hsinchu (TW)

(21) Appl. No.: 11/744,459

(22) Filed: May 4, 2007

(30) Foreign Application Priority Data
Jan. 15, 2007 (TW) 096101494

(51) Int. Cl. H01L 21/306

(52) U.S. Cl. 216/67

(57) ABSTRACT

A method for processing a wafer in a reaction chamber is provided. The method includes the following steps: performing an over-etching, so as to have a sufficient oxide-layer isolation depth between metal wires; applying high-bias, high-watt plasma, so as to remove a reaction polymer on a surface of the wafer, and to remove the reaction polymer on the surface of the reaction chamber; and performing a static-eliminating procedure, so as to remove the static charges on the wafer, and then delivering the wafer out of the reaction chamber. Through the method with the high-bias, high-watt plasma of the present invention, the following efficacies can be achieved: (1) eliminating blemishes on the produced wafer; (2) prolonging a corrosion time of an aluminum-copper wire on the surface of the wafer; (3) prolonging an average cycle period for cleaning the reaction chamber; (4) shortening the time in the next acid tank; and (5) enhancing the yield of each wafer by 2-5%.

### FIELD OF THE INVENTION

The present invention relates to a method for processing a wafer. More particularly, the present invention relates to a method for processing a wafer with a step of applying high-bias, high-watt plasma in a reaction chamber, so as to remove a reaction polymer on a surface of a wafer and to remove the reaction polymer on the surface of the reaction chamber.

### DESCRIPTION OF THE PRIOR ART

The common process for fabricating a wafer does not remove a reaction polymer on the surface of the wafer by utilizing high-bias, high-watt plasma, but only carries away a small amount of the reaction polymer from the surface of the wafer by using a gas flow and a low pressure, which results in a poor effect.

During the conventional process for fabricating a wafer 1, as shown in FIG. 1, a reaction polymer 2 generated after etching the wafer 1 will be attached to the surface of the wafer 1, which easily causes the following defects:

1. if it takes a long time to react in the acid tank, the acid solution should be changed frequently, or the acid tank is often contaminated by the reaction polymer;

2. the chlorine-containing reaction polymer 2 on the surface of the wafer 1 is likely to corrode the aluminum wire on the surface on the wafer 1, which causes a disconnection of the aluminum wire or an increment in the impedance and capacitance. As a result, the wafer 1 is discarded, or the yield and the reliability of the wafer 1 are severely affected;

3. the reaction polymer 2, which is attached to both sides of the aluminum wire and forms a thick rabbit ear, cannot be easily removed in the acid tank, which causes difficulties in the subsequent step of filling oxide, and thus the rabbit ear is not allowed to exist; and

4. a large amount of micro reaction polymer 2 has accumulated around the edge of the wafer 1, so that the micro reaction polymer 2 flows back to the surface of the wafer 1 upon being etched, which results in a low yield.

### SUMMARY OF INVENTION

In the present invention, a step of applying high-bias, high-watt plasma is added between the over-etching step and the static-eliminating step during a conventional process for fabricating a wafer 1, so that the reaction polymer 2 on the wafer 1 can be effectively removed, without affecting the original specification of the wafer 1.

The present invention relates to a method for processing a wafer 1 in a reaction chamber. The method includes the following steps: performing an over-etching, so as to have a sufficient oxide layer isolation depth between metal wires; applying high-bias, high-watt plasma, so as to remove a reaction polymer 2 on the surface of the wafer 1, and to remove the reaction polymer 2 on the surface of the reaction chamber; and performing a static-eliminating procedure, so as to eliminate the static charges on the wafer 1, and then, delivering the wafer out of the reaction chamber.

### BRIEF DESCRIPTION OF THE DRAWINGS

FIG. 1 shows a reaction polymer attached to a surface of a wafer during a conventional process for fabricating the wafer;

FIG. 2 shows that the reaction polymer is no longer attached to the surface of the wafer after the step of applying high-bias, high-watt plasma of the present invention; and

FIG. 3 is a flow chart for implementing the present invention.

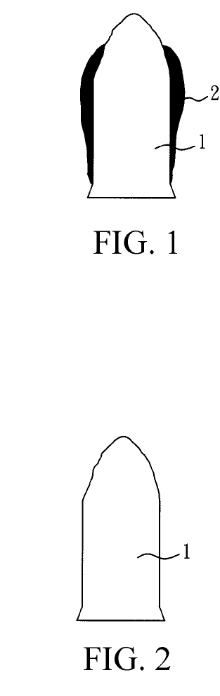

### DETAILED DESCRIPTION

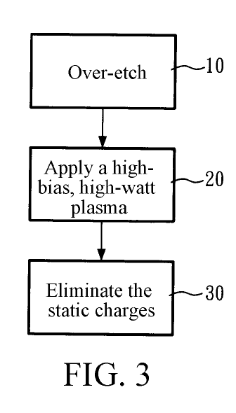

In the present invention, a step of applying high-bias, high-watt plasma is added between the over-etching step and the static-eliminating step during a conventional process for fabricating a wafer 1. As shown in FIG. 2, through the method of the present invention, a reaction polymer 2 on the wafer 1 can be effectively removed, without affecting the original specification of the wafer 1.

FIG. 3 is a flow chart for implementing the present invention, which includes the following steps: performing an over-etching (Step 10), so as to have a sufficient isolation depth of an oxide layer between metal wires; applying high-bias, high-watt plasma (Step 20), so as to remove a reaction polymer 2 on the surface of the wafer 1, and to remove the reaction polymer 2 on the surface of a reaction chamber; and performing a static-eliminating step (Step 30), so as to eliminate the static charges on the wafer 1, and then, delivering the wafer out of the reaction chamber. In Step 20, the time for applying the plasma falls in a range from 5 to 60 seconds, in which the plasma includes boron trichloride (BCl₃) and an argon gas (Ar); the pressure of the plasma falls in a range from 6 to 12 mTorr; the upper power and the lower power of the plasma fall in a range from 300 to 1200 watts and in a range from 250 to 900 watts respectively; and the flow rates of BCl₃ and Ar contained in the plasma fall in a range from 10 to 200 sccm and in a range from 100 to 1000 sccm respectively. Additionally, BCl₃ contained in the plasma can be replaced by a nitrogen gas or an oxygen gas, and the flow of the nitrogen gas or the oxygen gas falls in a range from 10 to 200 sccm.

Through the method of the present invention, the following effects can be achieved.

1. A reaction polymer 2 close to the surface of a reaction chamber of a wafer 1 can be removed with high-bias, high-watt plasma of the present invention, so as to prevent the reaction polymer 2 from returning to the surface of the wafer 1 to hamper etching or cause partial etching, and thus, blemishes during the process for fabricating the wafer 1 can be reduced, and the yield of the wafer can be improved;

2. The “rabbit ear” on each side of an aluminum wire and the reaction polymer 2 can be effectively removed by the high-bias plasma of the present invention, and the corrosion-resistant time for an aluminum-copper wire on the surface of the wafer 1 can be greatly prolonged over 96 hours, in the absence of the reaction polymer 2;

3. the reaction polymer 2 on the surface of the reaction chamber can also be removed after the step of applying the high-bias, high-watt plasma of the present invention, so that the average cycle period for cleaning the reaction chamber is prolonged;

4. the reaction polymer 2 on the surface of the wafer 1 has almost been removed, so that the time in the next acid tank is greatly reduced; and

5. the yield of each wafer can be enhanced by 2-5%.

What is claimed is:

1. A method for processing a wafer in a reaction chamber, comprising the following steps:
performing an over-etching step, to have a sufficient oxide-layer isolation depth between metal wires;
applying high-bias, high-watt plasma, to remove a reaction polymer on a surface of the wafer, and to remove the reaction polymer on the surface of the reaction chamber; and
performing a static charge-eliminating step, to eliminate static charges on the wafer, and then, to deliver the wafer out of the reaction chamber.

2. The method as claimed in claim 1, wherein the pressure of the plasma falls in a range from 6 to 12 mTorr.

3. The method as claimed in claim 1, wherein the upper power of the plasma falls in a range from 300 to 1200 watts.

4. The method as claimed in claim 1, wherein the lower power of the plasma falls in a range from 250 to 900 watts.

5. The method as claimed in claim 1, wherein the plasma comprises a boron trichloride and an argon gas.

6. The method as claimed in claim 5, wherein boron trichloride is replaced by a nitrogen gas or an oxygen gas.

7. The method as claimed in claim 1, wherein the time for applying the plasma falls in a range from 5 to 60 seconds.

8. The method as claimed in claim 5, wherein the flow rate of the boron trichloride falls in a range from 10 to 200 sccm.

9. The method as claimed in claim 6, wherein the flow rate of the nitrogen gas or the oxygen gas falls in a range from 10 to 200 sccm.

10. The method as claimed in claim 5, wherein the flow rate of the argon gas falls in a range from 100 to 1000 sccm.
